(19) United States
(12) Patent Application Publication
(10) Pub. No.: US 2025/0107014 A1
(43) Pub. Date: Mar. 27, 2025

(54) DISPLAY MODULE AND PREPARATION METHOD THEREOF, AND DISPLAY DEVICE

(71) Applicant: Xiamen Tianma Display Technology Co., Ltd., Xiamen (CN)

(72) Inventors: Yicheng CHEN, Xiamen (CN); Yicai CHEN, Xiamen (CN)

(73) Assignee: Xiamen Tianma Display Technology Co., Ltd., Xiamen (CN)

(21) Appl. No.: 18/975,011

(22) Filed: Dec. 10, 2024

(30) Foreign Application Priority Data
Dec. 28, 2023 (CN) 202311839433.1

(51) Int. Cl. H05K 5/02

(52) U.S. Cl. CPC H05K 5/02

(57) ABSTRACT

A display module includes a display panel, a first support layer, a second support layer, a function layer, a binding element and a second bonding layer. The display panel includes a first segment, a second segment, and a bending portion. The binding element includes a first overlapping portion, a second overlapping portion, and a connection portion, where an accommodation space is formed between the connection portion and the function layer. The second bonding layer includes a first sub-bonding portion and a second sub-bonding portion. A sidewall of the second support layer close to the accommodation space is a first sidewall, the second sub-bonding portion is located in the accommodation space, and the second sub-bonding portion covers at least one of: at least part of the first sidewall or an edge of an overlapping region of the first overlapping portion and the second segment.

### CROSS-REFERENCE TO RELATED APPLICATION(S)

This disclosure claims priority to Chinese patent application No. 202311839433.1 filed with the China National Intellectual Property Administration (CNIPA) on Dec. 28, 2023, the disclosure of which is incorporated herein by reference in its entirety.

### TECHNICAL FIELD

The present disclosure relates to the field of display technologies, for example, a display module, a preparation method of a display module, and a display device.

### BACKGROUND

At present, display technologies permeate various aspects of people's daily life. In electronic products such as a computer, a mobile phone, and a smart watch, the display technologies are required to implement the display function, so as to facilitate the man-machine interaction and thus improve the use experience of the user.

In a display module, poor reliability of the display module caused by intrusion of the water vapor in the external air exists.

### SUMMARY

In view of this, the present disclosure provides a display module, a preparation method of a display module, and a display device.

The present disclosure provides a display module. The display module includes a display panel, a first support layer, a second support layer, a function layer, a binding element, a first bonding layer and a second bonding layer. The display panel includes a first segment, a second segment, and a bending portion connecting the first segment to the second segment, where the first segment and the second segment are disposed opposite to each other in a direction perpendicular to a plane where the first segment is located, the first segment includes a display region, and the second segment includes a binding region. The first support layer is located on a side of the first segment close to the second segment. The second support layer is located on a side of the second segment close to the first segment. The function layer is located between the first support layer and the second support layer. The binding element includes a first overlapping portion, a second overlapping portion, and a connection portion connecting the first overlapping portion to the second overlapping portion, where the first overlapping portion is in binding connection with the binding region, the second overlapping portion is connected to the function layer through the first bonding layer, and an accommodation space is formed between the connection portion and the function layer. The second bonding layer includes a first sub-bonding portion and a second sub-bonding portion that are in mutual contact, where the first sub-bonding portion is located between the second support layer and the function layer. A sidewall of the second support layer close to the accommodation space is a first sidewall, and the second sub-bonding portion is located in the accommodation space and covers at least one of: at least part of the first sidewall or an edge of an overlapping region of the first overlapping portion and the second segment.

The present disclosure further provides a preparation method of a display module, and this method is used for preparing the display module described above. The preparation method of the display module includes that: a display panel is provided, where the display panel includes a first segment, a second segment, and a bending portion connecting the first segment to the second segment, the first segment includes a display region, and the second segment includes a binding region; a first support layer is formed on a side of the first segment, and a second support layer is formed on a side of the second segment; a binding element is provided, where the binding element includes a first overlapping portion, a second overlapping portion, and a connection portion connecting the first overlapping portion to the second overlapping portion, and the first overlapping portion is in binding connection with the binding region; a function layer is formed on a side of the first support layer away from the first segment; a bonding structure is provided, where the bonding structure includes a first protective film, a second protective film, and a first bonding layer and a second bonding layer that are located between the first protective film and the second protective film, and the second bonding layer includes a first sub-bonding portion and a second sub-bonding portion which are contacted with each other; the first protective film is removed, the first bonding layer and the second bonding layer are attached to a side of the function layer away from the first segment, and the second protective film is removed; and the display panel is bent so that the second overlapping portion is connected to the function layer through the first bonding layer, and the second support layer is connected to the function layer through the first sub-bonding portion, where an accommodation space is formed between the connection portion and the function layer, a sidewall of the second support layer close to the accommodation space is a first sidewall, and the second sub-bonding portion is located in the accommodation space and covers at least one of: at least part of the first sidewall or an edge of an overlapping region of the first overlapping portion and the second segment.

The present disclosure further provides a display device including the display module described above.

### BRIEF DESCRIPTION OF DRAWINGS

FIG. 1 is a schematic structural diagram of a display module;

FIG. 2 is a schematic structural diagram of a display module according to an embodiment of the present disclosure;

FIG. 3 is a schematic structural diagram of another display module according to an embodiment of the present disclosure;

FIG. 4 is a schematic structural diagram of still another display module according to an embodiment of the present disclosure;

FIG. 5 is a schematic structural diagram of still another display module according to an embodiment of the present disclosure;

FIG. 6 is a schematic structural diagram of still another display module according to an embodiment of the present disclosure;

FIG. 7 is a schematic structural diagram of still another display module according to an embodiment of the present disclosure;

FIG. 8 is a schematic structural diagram of still another display module according to an embodiment of the present disclosure;

FIG. 9 is a schematic structural diagram of a second sub-bonding portion and a second support layer according to an embodiment of the present disclosure;

FIG. 10 is a schematic structural diagram of another second sub-bonding portion and another second support layer according to an embodiment of the present disclosure;

FIG. 11 is a schematic structural diagram of a second sub-bonding portion, a second support layer, and a function layer according to an embodiment of the present disclosure;

FIG. 12 is a schematic structural diagram of another second sub-bonding portion, another second support layer, and another function layer according to an embodiment of the present disclosure;

FIG. 13 is a schematic structural diagram of still another display module according to an embodiment of the present disclosure;

FIG. 14 is a schematic structural diagram of still another display module according to an embodiment of the present disclosure;

FIG. 15 is a schematic structural diagram of still another display module according to an embodiment of the present disclosure;

FIG. 16 is a schematic flowchart of a preparation method of a display module according to an embodiment of the present disclosure;

FIG. 17 is a schematic diagram of a structure obtained in step S10 in a preparation method of a display module according to an embodiment of the present disclosure;

FIG. 18 is a schematic diagram of a structure obtained in step S20 in a preparation method of a display module according to an embodiment of the present disclosure;

FIG. 19 is a schematic diagram of a structure obtained in step S30 in a preparation method of a display module according to an embodiment of the present disclosure;

FIG. 20 is a schematic diagram of a structure obtained in step S40 in a preparation method of a display module according to an embodiment of the present disclosure;

FIG. 21 is a schematic diagram of a structure obtained in step S50 in a preparation method of a display module according to an embodiment of the present disclosure;

FIG. 22 is a schematic diagram of a structure obtained in step S60 in a preparation method of a display module according to an embodiment of the present disclosure;

FIG. 23 is a schematic diagram of a structure obtained in step S70 in a preparation method of a display module according to an embodiment of the present disclosure;

FIG. 24 is a schematic structural diagram of a bonding structure according to an embodiment of the present disclosure;

FIG. 25 is a schematic structural diagram of another bonding structure according to an embodiment of the present disclosure;

FIG. 26 is a schematic structural diagram of still another bonding structure according to an embodiment of the present disclosure;

FIG. 27 is a schematic structural diagram of still another bonding structure according to an embodiment of the present disclosure; and

FIG. 28 is a schematic top view of a display device according to an embodiment of the present disclosure.

### DETAILED DESCRIPTION

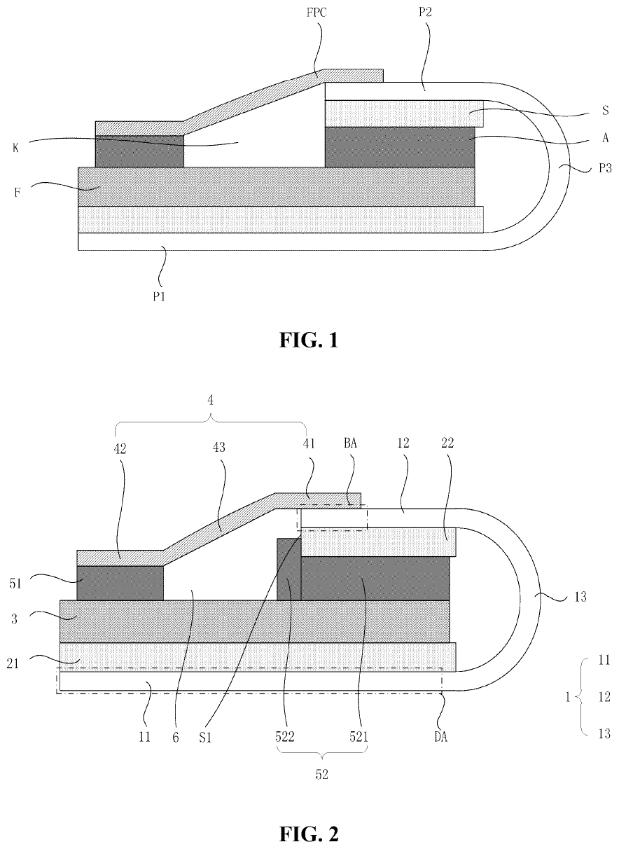

Referring to FIG. 1, FIG. 1 is a schematic structural diagram of a display module. The display module includes a display panel. The display panel includes a first segment P1, a second segment P2, and a bending region P3 located between the first segment P1 and the second segment P2. The first segment P1 is configured to display, and the second segment P2 is configured to bind some binding elements, such as a flexible printed circuit FPC or a driver chip integrated circuit (IC). A function layer F is further disposed between the first segment P1 and the second segment P2.

After the flexible printed circuit FPC is bound, one end of the flexible printed circuit FPC is connected to the second segment P2, and another end of the flexible printed circuit FPC is attached to a side of the function layer F. It is found that in this case, an accommodation space K is formed between the flexible printed circuit FPC and the function layer F, and water vapor in the external air may enter the accommodation space K, so that film layers between the second segment P2 and the function layer F are separated, for example, a support layer S and a bonding layer A on a side of the second segment P2 are separated, whereby the reliability of the display module is poor. Moreover, the water vapor may also intrude into the portion of the flexible printed circuit FPC and the second segment P2 that are bound, thereby resulting in corrosion at a connection between the flexible printed circuit FPC and the second segment P2, and the poor binding, which may also lead to the poor reliability of the display module.

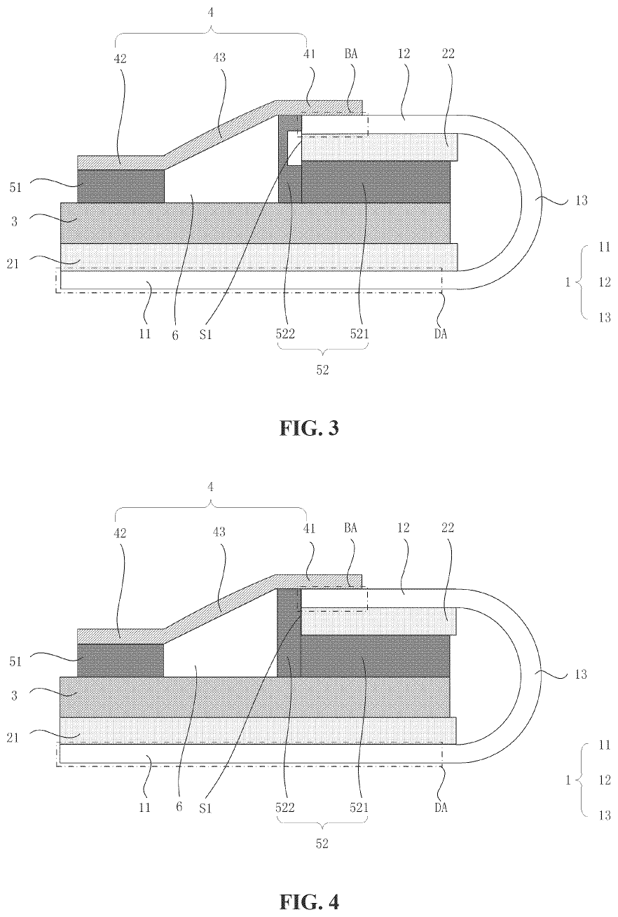

To avoid the above-described situation, an embodiment of the present disclosure provides a display module. Referring to FIG. 2 to FIG. 4, FIG. 2 is a schematic structural diagram of a display module according to an embodiment of the present disclosure, FIG. 3 is a schematic structural diagram of another display module according to an embodiment of the present disclosure, and FIG. 4 is a schematic structural diagram of still another display module according to an embodiment of the present disclosure. The display module includes a display panel 1, a first support layer 21, a second support layer 22, a function layer 3, a binding element 4, a first bonding layer 51, and a second bonding layer 52. The display panel 1 includes a first segment 11, a second segment 12, and a bending portion 13 connecting the first segment 11 to the second segment 12. The first segment 11 and the second segment 12 are disposed opposite to each other in a direction perpendicular to a plane where the first segment 11 is located. The first segment 11 includes a display region DA, and the second segment 12 includes a binding region BA. The first support layer 21 is located on a side of the first segment 11 close to the second segment 12. The second support layer 22 is located on a side of the second segment 12 close to the first segment 11. The function layer 3 is located between the first support layer 21 and the second support layer 22. The binding element 4 includes a first overlapping portion 41, a second overlapping portion 42, and a connection portion 43 connecting the first overlapping portion 41 to the second overlapping portion 42. The first overlapping portion 41 is in binding connection with the binding region BA, and the second overlapping portion 42 is connected to the function layer 3 through the first bonding layer 51. An accommodation space 6 is formed between the connection portion 43 and the function layer 3. The second bonding layer 52 includes a first sub-bonding portion 521 and a second sub-bonding portion 522 that are in mutual contact, and the first sub-bonding portion 521 is located between the second support layer 22 and the function layer 3.

A sidewall of the second support layer 22 close to the accommodation space 6 is a first sidewall S1, and the second sub-bonding portion 522 is located in the accommodation space 6 and covers at least a part of the first sidewall S1 and/or covers an edge of an overlapping region of the first overlapping portion 41 and the second segment 12.

It should be noted that the display panel provided in the embodiments of the present disclosure may be a liquid crystal display panel, an organic light-emitting display panel, a Mini light-emitting diode (LED) display panel, or a Micro LED display panel, which is not limited herein.

Exemplarily, the binding element 4 includes a flexible printed circuit. A first binding pad is disposed on the first overlapping portion 41 of the binding element 4, a second binding pad corresponding to the first binding pad is disposed in the binding region, and the first binding pad and the second binding pad may be bound and connected by using anisotropic conductive glue.

In the embodiments of the present disclosure, the second sub-bonding portion 522 may cover only the first sidewall S1 (as shown in FIG. 2), or may cover only the edge of the overlapping region of the first overlapping portion 41 and the second segment 12 (as shown in FIG. 3), or may cover both the first sidewall S1 and the edge of the overlapping region of the first overlapping portion 41 and the second segment 12 (as shown in FIG. 4). The edge of the overlapping region of the first overlapping portion 41 and the second segment 12 may be an edge of the overlapping region of the first overlapping portion 41 and the second segment 12 close to the accommodation space 6.

In the above-described display module, the display panel includes the first segment 11, the second segment 12, and the bending portion 13 located between the first segment 11 and the second segment 12. The first segment 11 and the second segment 12 are disposed opposite to each other in the direction perpendicular to the plane where the first segment 11 is located. The first support layer 21 and the second support layer 22 are disposed between the first segment 11 and the second segment 12, so as to separately support and protect the first segment 11 and the second segment 12. The function layer 3 is further disposed between the first support layer 21 and the second support layer 22. The first overlapping portion 41 of the binding element 4 is in binding connection with the binding region BA, and the second overlapping portion 42 is connected to the function layer 3 through the first bonding layer 51. The accommodation space 6 is formed between the connection portion 43 of the binding element 4 and the function layer 3. In the embodiments of the present disclosure, the second sub-bonding portion 522 of the second bonding layer 52 is located in the accommodation space 6 and covers at least the part of the first sidewall S1 of the second support layer 22, so that the water vapor in the external air can be prevented from being intruded through the accommodation space 6, thereby avoiding the film layer separation between the second support layer 22 and the first sub-bonding portion 521 on one side of the second support layer 22 and improving the reliability of the display module. Moreover, the second sub-bonding portion 522 is enabled to cover the edge of the overlapping region of the first overlapping portion 41 and the second segment 12, so that the portion of the binding element 4 and the second segment 12 that are bound may be avoided from being corroded by water vapor, thereby improving the binding yield and improving the reliability of the display module.

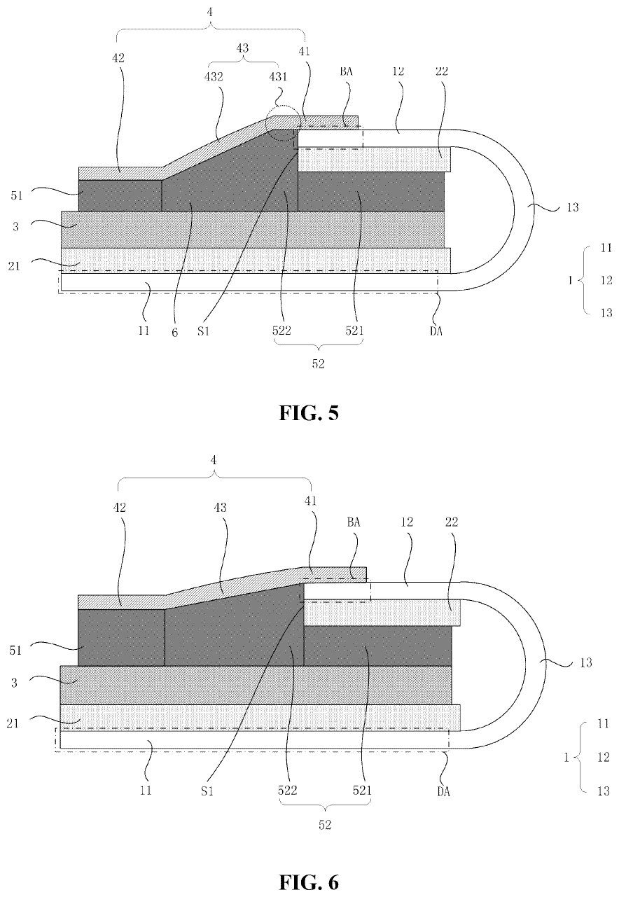

In some embodiments, referring to FIG. 5, FIG. 5 is a schematic structural diagram of still another display module according to an embodiment of the present disclosure. The second sub-bonding portion 522 is filled in the accommodation space 6 and is in contact with the connection portion 43, the first bonding layer 51 and the function layer 3. That is, the second sub-bonding portion 522 may completely fill the accommodation space 6 between the connection portion 43 and the function layer 3. In this way, on one hand, the water vapor may not enter the accommodation space 6, and on the other hand, the second sub-bonding portion 522 may be used to support the connection portion 43 of the binding element 4. In this way, when the connection portion 43 is under an external force, the connection portion 43 cannot be collapsed or deformed, so that the binding element 4 can be stable, and the binding element 4 is prevented from being damaged by the external force.

In some embodiments, continuing to refer to FIG. 5, a distance between the connection portion 43 and the function layer 3 gradually decreases in a direction in which the first overlapping portion 41 is directed towards the second overlapping portion 42, and the thickness of the second sub-bonding portion 522 gradually decreases in the direction in which the first overlapping portion 41 is directed towards the second overlapping portion 42.

Since the high number of film layers are disposed between the first segment 11 and the second segment 12, the plane where the first overlapping portion 41 is located and the plane where the second overlapping portion 42 is located are both parallel to the plane where the first segment 11 is located. After the binding element 4 is bound, a height difference is formed between the first overlapping portion 41 and the second overlapping portion 42, so that a surface of the connection portion 43 is inclined. After the binding element 4 is bound, the binding position is fixed; if the middle connection portion 43 is deformed, the first overlapping portion 41 and the second overlapping portion 42 at two ends may be stressed (for example, pulled), resulting in the poor binding. In the above-described display module, the thickness of the second sub-bonding portion 522 gradually decreases in the direction in which the first overlapping portion 41 is directed towards the second overlapping portion 42, that is, in terms of the change rule of the thickness of the second sub-bonding portion 522, the thickness of the second sub-bonding portion 522 varies with the inclination trend of the connection portion 43, so that the second sub-bonding portion 522 supports the connection portion 43 without changing the inclination trend of the connection portion 43, so as to enable the shape of the connection portion 43 to be stable, thereby ensuring the stability of the connection between the first overlapping portion 41 and the second overlapping portion 42.

Exemplarily, the maximum thickness of the second sub-bonding portion 522 is equal to the sum of thicknesses of the second segment 12, the second support layer 22, and the first sub-bonding portion 521. In this way, it can be ensured that the variation range of the thickness of the second sub-bonding portion 522 does not exceed the maximum distance between the connection portion 43 and the function layer 3, so that the connection portion 43 is not easily deformed while the connection portion 43 is supported.

Exemplarily, the minimum thickness of the second sub-bonding portion 522 is equal to the thickness of the first bonding layer 51.

As shown in FIG. 5, the maximum thickness of the second sub-bonding portion 522 is the thickness of one end of the second sub-bonding portion 522 close to the first sub-bonding portion 521, and the minimum thickness of the second sub-bonding portion 522 is the thickness of one end of the second sub-bonding portion 522 close to the first bonding layer 51.

In some embodiments, referring to FIG. 6, FIG. 6 is a schematic structural diagram of still another display module according to an embodiment of the present disclosure. The thickness of the first sub-bonding portion 521 is less than or equal to the thickness of the first bonding layer 51.

Since a height difference exists between the first overlapping portion 41 and the second overlapping portion 42, the stress concentration is easily caused on the edge of the overlapping region of the first overlapping portion 41 and the second segment 12. In the above-described display module, the thickness of the first sub-bonding portion 521 is made to be less than or equal to the thickness of the first bonding layer 51, whereby a height difference between the first overlapping portion 41 and the second overlapping portion 42 can be reduced, thereby slowing down the inclination trend of the connection portion 43 and avoiding stress concentration.

In some embodiments, referring to FIG. 5, the connection portion 43 includes a plane portion 431 and an oblique portion 432 that are connected to each other, the plane portion is close to the first overlapping portion 41, and a plane where the plane portion 431 is located is located on the same plane as a plane where the first overlapping portion 41 is located. In this way, the stress concentration on the edge of the overlapping region of the first overlapping portion 41 and the second segment 12 may be avoided.

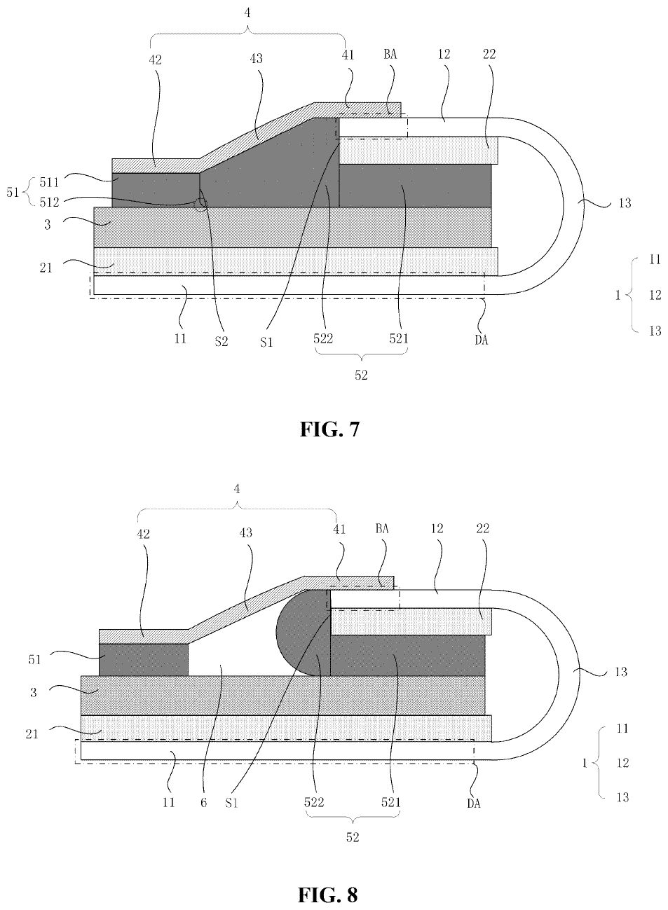

In some embodiments, referring to FIG. 7, FIG. 7 is a schematic structural diagram of still another display module according to an embodiment of the present disclosure. The first bonding layer 51 includes a main portion 511 and an extension portion 512, and the extension portion 512 is located on a side of the main portion 511 close to the second bonding layer 52. The extension portion 512 includes an arc surface, and the arc surface of the extension portion 512 is bent towards the function layer 3. A sidewall of the main portion 511 close to the second bonding layer 52 is a second sidewall S2, and the arc surface of the extension portion 512 is connected to the second sidewall S2. The second sub-bonding portion 522 is in contact with the arc surface of the extension portion 512 and the second sidewall S2.

In the above-described display module, the first bonding layer 51 includes two portions, i.e., a main portion 511 and an extension portion 512, and the extension portion 512 is closer to the second bonding layer 52. The surface of the extension portion 512 is made to be the arc surface, so that the second sub-bonding portion 522 can be fully contacted with the first bonding layer 51, dead spots which are difficult to be filled are avoided, whereby the external water vapor can be prevented from entering the accommodation space as much as possible.

In some embodiments, referring to FIG. 8, FIG. 8 is a schematic structural diagram of still another display module according to an embodiment of the present disclosure. A surface of the second sub-bonding portion 522 close to the first bonding layer 51 is an arc surface.

It should be understood that in the display module, a side of the connection portion 43 close to the function layer 3 is unsupported, which causes the connection portion 43 to be a weakness point. Once an external force is applied to the connection portion 43, the connection portion 43 may be deformed or even broken, which affects a line on the binding element. In the above-described display module, a surface of the second sub-bonding portion 522 close to the first bonding layer 51 is disposed as the arc surface, and when the connection portion 43 is subjected to the external force, a surface of the connection portion 43 close to the accommodation space 6 may be abutted, so that the connection portion 43 cannot be further deformed towards the accommodation space. Moreover, since the surface of the second sub-bonding portion 522 close to the first bonding layer 51 is the arc surface, the connection portion 43 is not damaged after being contacted with the second sub-bonding portion 522 by an external force, so that the surface of the connection portion 43 close to the accommodation space 6 can be protected.

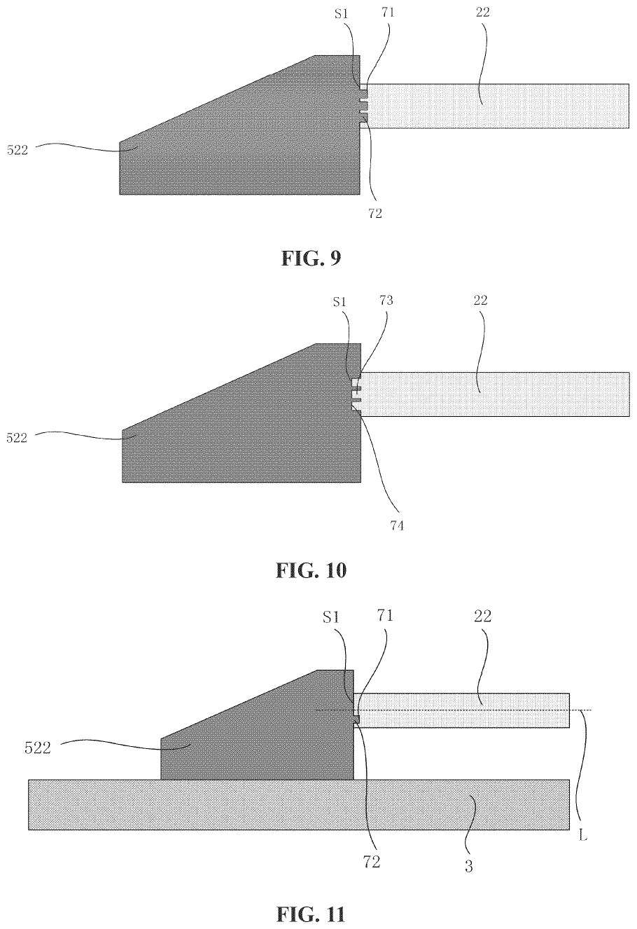

In some embodiments, referring to FIG. 9 and FIG. 10, FIG. 9 is a schematic structural diagram of a second sub-bonding portion and a second support layer according to an embodiment of the present disclosure; and FIG. 10 is a schematic structural diagram of another second sub-bonding portion and another second support layer according to an embodiment of the present disclosure. The first sidewall S1 includes at least one first groove 71, a surface of the second sub-bonding portion 522 away from the first bonding layer 51 includes at least one first protrusion 72, and a first protrusion of the at least one first protrusion 72 is fitted into a respective one of the at least one first groove 71. Alternatively, the first sidewall S1 includes at least one second protrusion 73, a surface of the second sub-bonding portion 522 away from the first bonding layer 51 includes at least one second groove 74, and a second protrusion of the at least one second protrusion 73 is fitted into a respective one of the at least one second groove 74.

It should be noted that the number of first protrusions, second protrusions, first grooves, and second grooves are not limited in the embodiments of the present disclosure, and may be set according to requirements in practical application.

In the above-described display module, the first groove 71 may be disposed on the first sidewall S1, and the first protrusion 72 is disposed on the surface of the second sub-bonding portion 522 away from the first bonding layer 51; or the second protrusion 73 is disposed on the first sidewall S1, and the second groove 74 is disposed on the surface of the second sub-bonding portion 522 away from the first bonding layer 51. A contact area between the second support layer 22 and the second sub-bonding portion 522 may be increased by fitting the protrusion and the groove, thereby enhancing the reliability of connection between the second support layer 22 and the second sub-bonding portion 522, preventing the separation of the second support layer 22 and the second sub-bonding portion 522, and preventing water vapor from entering from a contact position between the second support layer 22 and the second sub-bonding portion 522.

In some embodiments, a surface of the first sidewall S1 and a surface of the second sub-bonding portion 522 may be disposed in a wave shape or another type of fluctuation shape so as to increase the contact area between the first sidewall S1 and the second sub-bonding portion 522, which is not limited in the embodiments of the present disclosure.

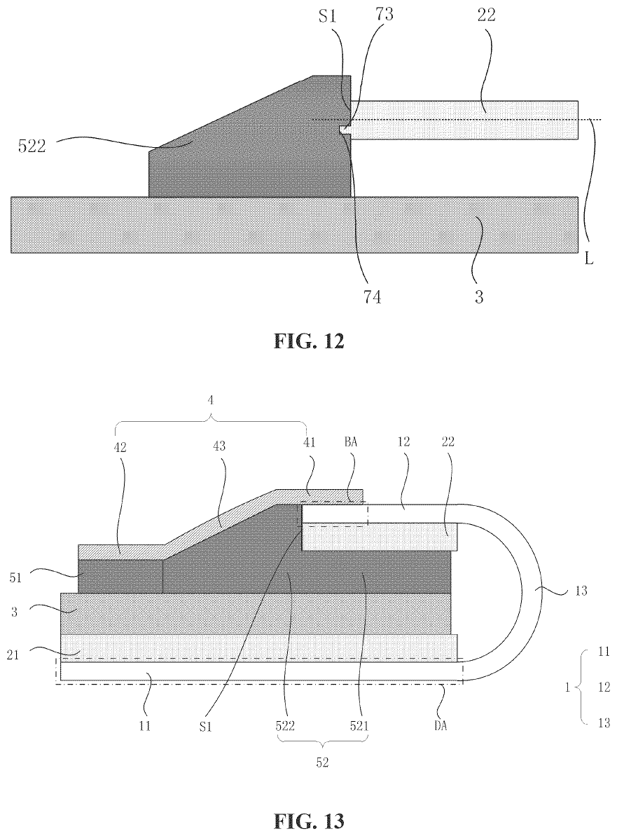

In some embodiments, referring to FIG. 11 and FIG. 12, FIG. 11 is a schematic structural diagram of a second sub-bonding portion, a second support layer, and a function layer according to an embodiment of the present disclosure; and FIG. 12 is a schematic structural diagram of another second sub-bonding portion, another second support layer, and another function layer according to an embodiment of the present disclosure.

The first sidewall S1 includes at least one first groove 71, and the first groove 71 is located in a portion of the first sidewall S1 close to the function layer 3. Alternatively, the first sidewall S1 includes at least one second protrusion 73, and the at least one second protrusion 73 is located in a portion of the first sidewall S1 close to the function layer 3.

As shown in FIG. 11 and FIG. 12, the display module includes a virtual split line L, where the virtual split line Lis parallel to a plane where the function layer 3 is located, and the first sidewall S1 is divided into two equal portions by the virtual split line L. One portion is close to the function layer 3, and the other portion is away from the function layer 3. The first groove 71 or the second protrusion 73 located on the first sidewall S1 is disposed in a portion close to the function layer 3. It should be understood that the second sub-bonding portion 522 may be formed by using a glue that needs to be cured, that is, when the second sub-bonding portion 522 is firstly formed, the second sub-bonding portion 522 has a certain fluidity. Because of the gravity effect, before being cured, the flowing glue is more likely to be concentrated in a position closer to the function layer 3 in the accommodation space. Therefore, the first groove 71 is disposed in the portion of the first sidewall S1 closer to the function layer 3, so that the second sub-bonding portion 522 is easier to be filled in the first groove 71. Similarly, the second protrusion 73 is disposed in the portion of the first sidewall S1 closer to the function layer 3, it is easier for the second sub-bonding portion 522 to cover the second protrusion 73, so as to ensure the relatively large contact area between the second support layer 22 and the second sub-bonding portion 522.

In some embodiments, the hardness of the first sub-bonding portion 521 is greater than the hardness of the second sub-bonding portion 522.

In the above-described display module, the hardness of the first sub-bonding portion 521 may be set to be greater than the hardness of the second sub-bonding portion 522. In this way, the first sub-bonding portion 521 may have a certain strength, so that the first segment 11 and the second segment 12 can be strongly supported. The hardness of the second sub-bonding portion 522 may be set lower. When the connection portion 43 is subjected to the external force, the second sub-bonding portion 522 may buffer the connection portion 43 so as to protect the connection portion 43.

In some embodiments, the second sub-bonding portion 522 may be disposed as an adhesive layer having elasticity.

In some embodiments, referring to FIG. 13, FIG. 13 is a schematic structural diagram of still another display module according to an embodiment of the present disclosure. The first sub-bonding portion 521 and the second sub-bonding portion 522 form an integrative structure. The first bonding portion 521 and the second sub-bonding portion 522 are set as the integral structure, so that the preparation process of the display module can be simplified, and the preparation efficiency can be improved.

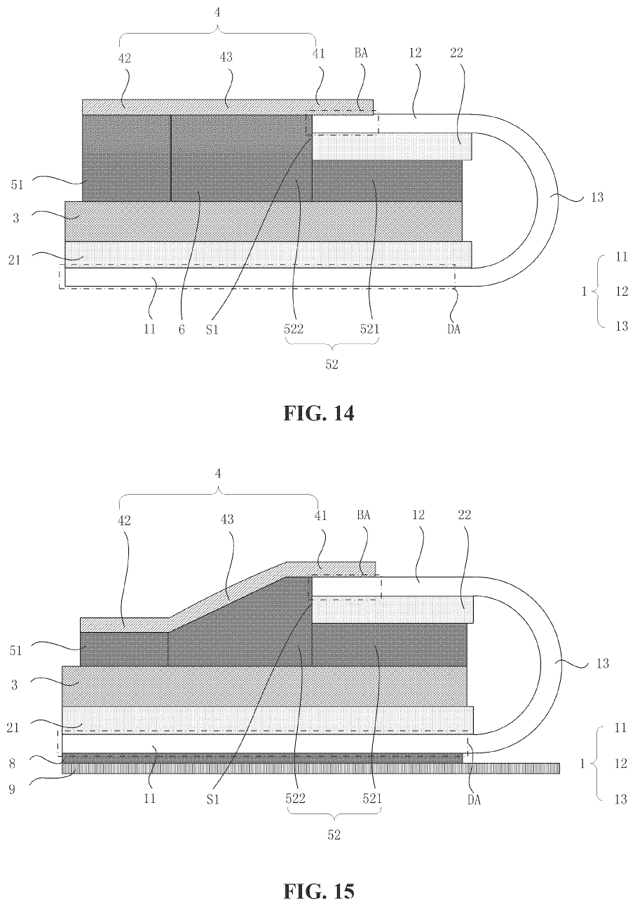

In some embodiments, referring to FIG. 14, FIG. 14 is a schematic structural diagram of still another display module according to an embodiment of the present disclosure. The distance between the first overlapping portion 41 and the function layer 3 is equal to the distance between the second overlapping portion 42 and the function layer 3. The thickness of the second sub-bonding portion 522 is equal at different positions of the second sub-bonding portion 522.

In the above-described display module, the distance between the first overlapping portion 41 and the function layer 3 is equal to the distance between the second overlapping portion 42 and the function layer 3, that is, the first overlapping portion 41 and the second overlapping portion 42 may be located on the same plane. Correspondingly, the connection portion 43, the first overlapping portion 41 and the second overlapping portion 42 may be located on the same plane, so that the height difference between the first overlapping portion 41 and the second overlapping portion 42 can be eliminated, and the stress concentration that appears in the foregoing may be avoided. The thickness of the second sub-bonding portion 522 may be set to be equal at different positions of the second sub-bonding portion 522, so as to better support the connection portion 43. It should be noted that the thickness of the second sub-bonding portion 522 is equal at different positions of the second sub-bonding portion 522, and the process error during preparation needs to be considered, as long as the thickness of the second sub-bonding portion 522 is basically equal at different positions of the second sub-bonding portion 522.

In some embodiments, the thickness of the first bonding layer 51 is the same as the thickness of the second sub-bonding portion 522, so that the first overlapping portion 41 and the second overlapping portion 42 are located on the same plane.

In some embodiments, the material of the first bonding layer 51 is different from the material of the second bonding layer 52.

In some embodiments, the first bonding layer 51 includes a conductive adhesive layer, and the conductive adhesive layer includes a conductive layer and adhesive layers on two sides of the conductive layer. The conductive layer is, for example, a copper layer, an aluminum layer, a gold layer, a silver layer, or an alloy of multiple metals.

In some embodiments, the first sub-bonding portion 521 and the second sub-bonding portion 522 each includes a composite adhesive layer. The composite adhesive layer is, for example, a thermoplastic polyester resin or other high molecular polymer adhesive layer. The material of the first sub-bonding portion 521 and the material of the second sub-bonding portion 522 may be the same or different, which is not limited in the embodiments of the present disclosure.

In some embodiments, the function layer 3 includes a composite film layer, and the composite film layer includes an adhesive layer, a metal layer, and foam disposed in a laminated manner.

In some embodiments, referring to FIG. 15, FIG. 15 is a schematic structural diagram of still another display module according to an embodiment of the present disclosure. The display module further includes an optical film layer 8 and a cover plate 9. The optical film layer 8 is located on a side of the first segment 11 away from the function layer 3. The cover plate 9 is located on a side of the optical film layer 8 away from the first segment 11. In some embodiments, the optical film layer includes a polarizer, and the polarizer may prevent the external ambient light from being incident on the metal film layer in the display panel and then being reflected into the human eyes, thereby affecting the display effect. The cover plate 9 may protect the structure on one side of the cover plate 9, so as to avoid damage to other structures in the display module. The optical film layer 8 and the cover plate 9 may be bonded by using an optical adhesive layer.

In other embodiments, the first segment further includes a color film layer, the color film layer includes a color barrier layer and a light shielding layer, and the color film layer may replace the polarizer, so that the display module is lighter and thinner.

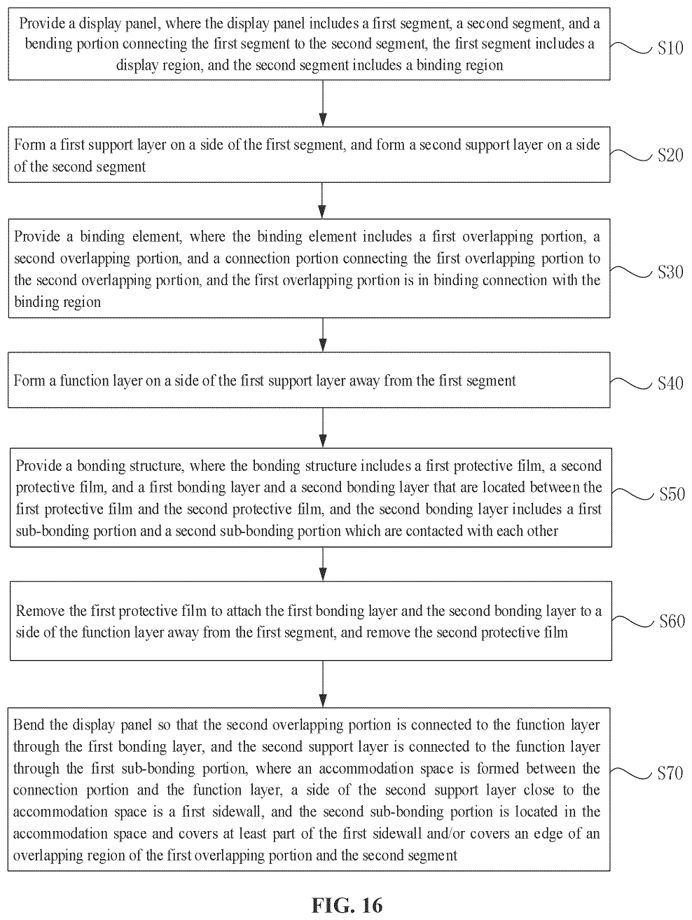

Based on the same concept, an embodiment of the present disclosure further provides a preparation method of a display module, so as to prepare the display module in the foregoing some embodiments. Referring to FIG. 16, FIG. 16 is a schematic flowchart of a preparation method of a display module according to an embodiment of the present disclosure. The preparation method of the display module includes the following steps.

In S10, a display panel is provided, where the display panel includes a first segment, a second segment, and a bending portion connecting the first segment to the second segment, the first segment includes a display region, and the second segment includes a binding region.

In S20, a first support layer is formed on a side of the first segment, and a second support layer is formed on a side of the second segment.

In S30, a binding element is provided, where the binding element includes a first overlapping portion, a second overlapping portion, and a connection portion connecting the first overlapping portion to the second overlapping portion, and the first overlapping portion is in binding connection with the binding region.

In S40, a function layer is formed on a side of the first support layer away from the first segment.

In S50, a bonding structure is provided, where the bonding structure includes a first protective film, a second protective film, and a first bonding layer and a second bonding layer that are located between the first protective film and the second protective film, and the second bonding layer includes a first sub-bonding portion and a second sub-bonding portion which are contacted with each other.

In S60, the first protective film is removed, the first bonding layer and the second bonding layer are attached to a side of the function layer away from the first segment, and the second protective film is removed.

In S70, the display panel is bent so that the second overlapping portion is connected to the function layer through the first bonding layer, and the second support layer is connected to the function layer through the first sub-bonding portion, where an accommodation space is formed between the connection portion and the function layer, a side of the second support layer close to the accommodation space is a first sidewall, and the second sub-bonding portion is located in the accommodation space and covers at least part of the first sidewall and/or covers an edge of an overlapping region of the first overlapping portion and the second segment.

In a preparation process of an existing display module, one end of the binding element is bound to the binding region of the display panel, and another end of the binding element is bonded to the function layer through one bonding layer. The support layer on a side of the binding region needs to be bonded to the function layer by using another bonding layer. Since protective films are provided on two sides of each bonding layer, the protective film needs to be torn down twice each time the bonding layer needs to be bonded, and the two bonding layers need to be torn up four times in total. This undoubtedly increases the preparation process steps and reduces the preparation efficiency. In the preparation process of the display module described above, a bonding structure may be provided. The bonding structure includes a first protective film and a second protective film, and a first bonding layer and a second bonding layer that are located between the first protective film and the second protective film. By integrally feeding the first bonding layer and the second bonding layer and sharing the first protective film and the second protective film, only the first protective film and the second protective film need to be torn off during subsequent bonding, that is, only two film peeling processes are required, so that the preparation process steps can be reduced, the preparation efficiency can be improved, and thus the preparation cost can be reduced. Technical effects that can be implemented by the display module in the foregoing some embodiments may also be implemented in the preparation method, and details are not described herein again.

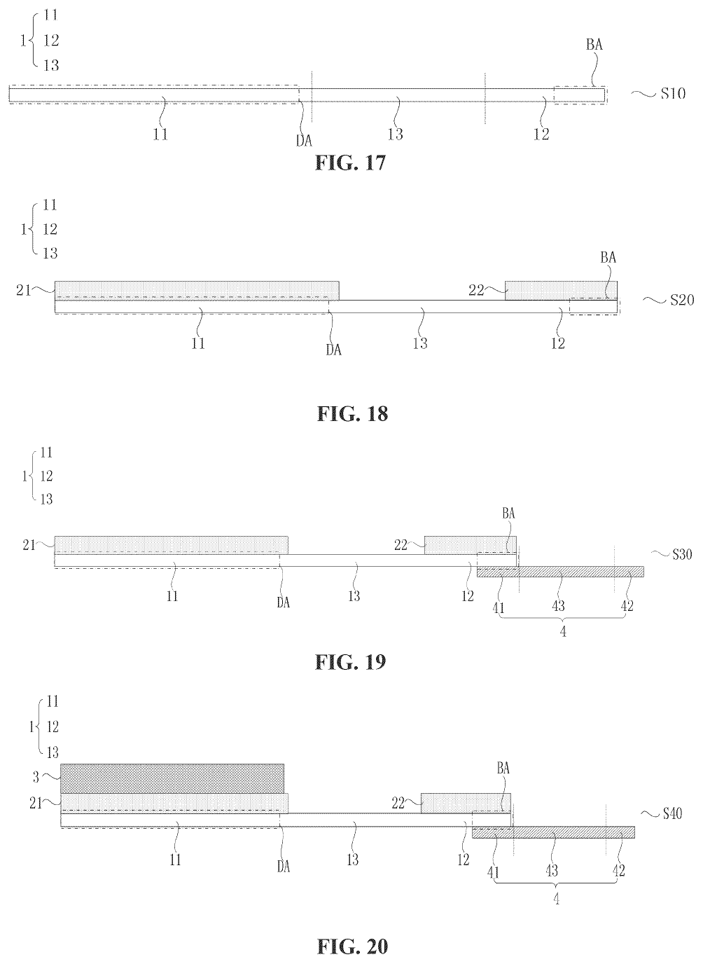

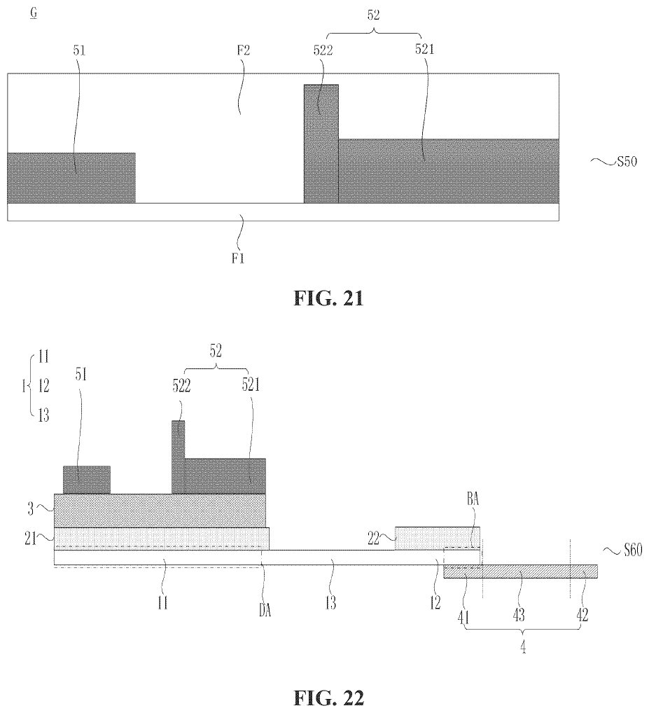

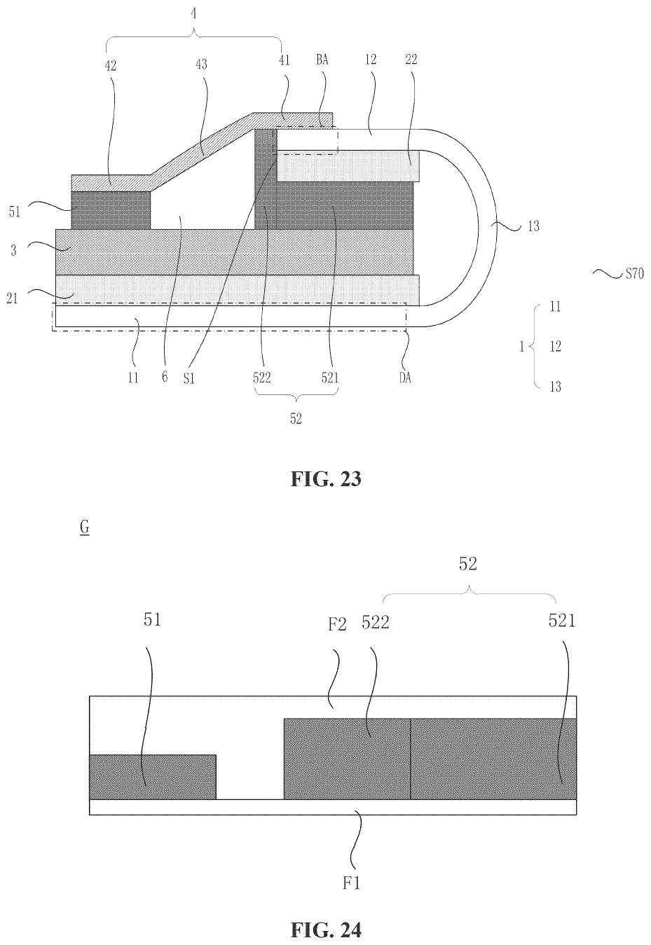

The preparation method described above is described in detail in the following in conjunction with FIG. 17 to FIG. 23. FIG. 17 is a schematic diagram of a structure obtained in step S10 in a preparation method of a display module according to an embodiment of the present disclosure; FIG. 18 is a schematic diagram of a structure obtained in step S20 in a preparation method of a display module according to an embodiment of the present disclosure; FIG. 19 is a schematic diagram of a structure obtained in step S30 in a preparation method of a display module according to an embodiment of the present disclosure; FIG. 20 is a schematic diagram of a structure obtained in step S40 in a preparation method of a display module according to an embodiment of the present disclosure; FIG. 21 is a schematic diagram of a structure obtained in step S50 in a preparation method of a display module according to an embodiment of the present disclosure; FIG. 22 is a schematic diagram of a structure obtained in step S60 in a preparation method of a display module according to an embodiment of the present disclosure; and FIG. 23 is a schematic diagram of a structure obtained in step S70 in a preparation method of a display module according to an embodiment of the present disclosure.

In step S10, referring to FIG. 17, a display panel 1 is provided. The display panel 1 includes a first segment 11, a second segment 12, and a bending portion 13 connecting the first segment 11 to the second segment 12. The first segment 11 includes a display region DA, and the second segment 12 includes a binding region BA.

In step S20, referring to FIG. 18, a first support layer 21 is formed on a side of the first segment 11, and a second support layer 22 is formed on a side of the second segment 12.

In some examples, to form the first support layer 21 and the second support layer 22, one support layer may be formed firstly, and then the support layer is patterned to remove a portion of the support layer corresponding to the bending portion 13, so as to form the first support layer 21 and the second support layer 22. In other examples, the first support layer 21 and the second support layer 22 may be formed separately.

In step S30, referring to FIG. 19, a binding element 4 is provided. The binding element 4 includes a first overlapping portion 41, a second overlapping portion 42, and a connection portion 43 connecting the first overlapping portion 41 to the second overlapping portion 42, and the first overlapping portion 41 is in binding connection with the binding region BA.

In some examples, the binding element 4 includes a flexible printed circuit. A first binding pad is disposed on the first overlapping portion 41 of the binding element, a second binding pad corresponding to the first binding pad is disposed in the binding region BA, and the first binding pad and the second binding pad may be bound and connected by using anisotropic conductive glue.

In step S40, referring to FIG. 20, a function layer 3 is formed on a side of the first support layer 21 away from the first segment 11.

The function layer 3 includes a composite film layer, and the composite film layer includes an adhesive layer, a metal layer, and foam which are disposed in a laminated manner.

In step S50, referring to FIG. 21, a bonding structure G is provided. The bonding structure G includes a first protective film F1, a second protective film F2, and a first bonding layer 51 and a second bonding layer 52 that are located between the first protective film F1 and the second protective film F2. The second bonding layer 52 includes a first sub-bonding portion 521 and a second sub-bonding portion 522 that are in mutual contact.

In some examples, a gap exists between the second sub-bonding portion 522 and the first bonding layer 51, that is, there is no contact between the second sub-bonding portion 522 and the first bonding layer 51. In this case, the second protective film F2 includes a protruding portion, and the protruding portion fills the gap between the second sub-bonding portion 522 and the first bonding layer 51, so as to isolate the second sub-bonding portion 522 and the first bonding layer 51.

In other examples, the second sub-bonding portion 522 may also be in contact with the first bonding layer 51.

In step S60, referring to FIG. 22, the first protective film F1 is removed, the first bonding layer 51 and the second bonding layer 52 are attached to a side of the function layer 3 away from the first segment 11, and the second protective film F2 is removed.

In step S70, referring to FIG. 23, the display panel 1 is bent, so that the second overlapping portion 42 is connected to the function layer 3 through the first bonding layer 51, and the second support layer 22 is connected to the function layer 3 through the first sub-bonding portion 521. An accommodation space 6 is formed between the connection portion 43 and the function layer 3. A sidewall of the second support layer 22 close to the accommodation space 6 is the first sidewall S1, and the second sub-bonding portion 522 is located in the accommodation space 6 and covers at least part of the first sidewall S1 and/or covers an edge of an overlapping region of the first overlapping portion 41 and the second segment 12.

It should be understood that, in the bonding structure G, the first sub-bonding portion 521 and the second sub-bonding portion 522 may be preset to a required shape (as shown in FIG. 21): the first sub-bonding portion 521 and the second sub-bonding portion 522 may also be disposed in a regular shape (as shown in FIG. 24), and adopt an adhesive with a certain fluidity, so as to adjust the shapes of the first sub-bonding portion 521 and the second sub-bonding portion 522 according to requirements in a subsequent preparation process, which is convenient for preparing the bonding structure G.

It should be further noted that FIG. 23 that is referred to in the foregoing description is a diagram corresponding to the formation of a second sub-bonding portion 522 that covers both the first sidewall S1 and the edge of the overlapping region of the first overlapping portion 41 and the second segment 12. In order to form the second sub-bonding portion 522 that covers only the first sidewall S1 as shown in FIG. 2, or the second sub-bonding portion 522 that covers only the edge of the overlapping region between the first overlapping portion 41 and the second portion 12 as shown in FIG. 3, shapes of the first sub-bonding portion 521 and the second sub-bonding portion 522 in the bonding structure may be adjusted.

In some embodiments, referring to FIG. 5, the second sub-bonding portion 522 is filled in the accommodation space 6 and is in contact with the connection portion 43, the first bonding layer 51, and the function layer 3.

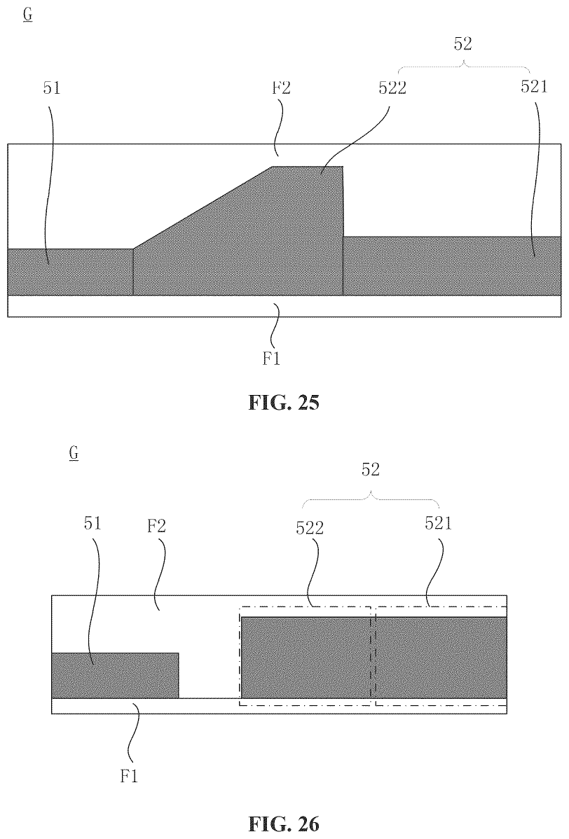

The second sub-bonding portion 522 may completely fill up the accommodation space 6 between the connection portion 43 and the function layer 3. In this way, on one hand, the water vapor cannot enter the accommodation space 6, and on the other hand, the second sub-bonding portion 522 may be used to support the connection portion 43 of the binding element 4. In this way, when the connection portion 43 is under the external force, the connection portion 43 is not prone to be collapsed and deformed, so that the binding element 4 can be kept stable, and thus the binding element 4 is prevented from being damaged by the external force. Correspondingly, as shown in FIG. 25, the second sub-bonding portion in the bonding structure G may also be preset to a required shape. In the bonding structure G, the second sub-bonding portion 522 is in contact with the first bonding layer 51.

In some embodiments, referring to FIG. 26, in the bonding structure, the first sub-bonding portion 521 and the second sub-bonding portion 522 form an integrative structure. In this way, a formation process of the second bonding layer 52 may be simplified.

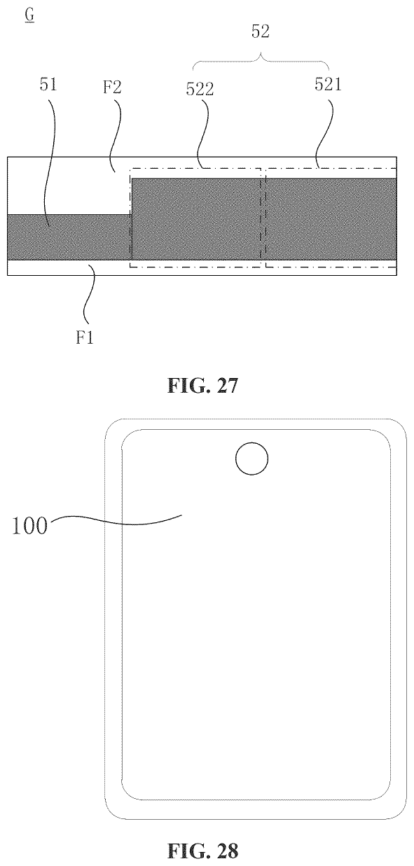

When the first sub-bonding portion 521 and the second sub-bonding portion 522 adopt an adhesive layer with a certain fluidity, the first sub-bonding portion 521 and the second sub-bonding portion 522 may jointly form a structure with a regular shape, so as to simplify the preparation process of the bonding structure G. For example, during the bonding, after being squeezed by the second support layer 22 and the function layer 3, the structure formed by the first sub-bonding portion 521 and the second sub-bonding portion 522 flows into the accommodation space, thereby covering at least part of the first sidewall S1 and/or covering the edge of the overlapping region of the first overlapping portion 41 and the second segment 12. In some embodiments, as shown in FIG. 27, when the first sub-bonding portion 521 and the second sub-bonding portion 522 form an integrative structure, the second sub-bonding portion 522 may also be disposed in contact with the first bonding layer 51.

Referring to FIG. 28, FIG. 28 is a schematic top view of a display device according to an embodiment of the present disclosure.

Based on the same concept, the present disclosure further provides a display device, and the display device includes the display module in the foregoing some embodiments. A specific structure of the display module 100 is the same as the foregoing some embodiments, and details are not described herein again. Apparently, the display device shown in FIG. 28 is merely a schematic description. The display device may be any electronic device that has a display function, such as a mobile phone, a tablet computer, a notebook computer, an electronic book, or a television, which is not limited in the embodiments of the present disclosure.

What is claimed is:

1. A display module, comprising:
a display panel comprising a first segment, a second segment, and a bending portion connecting the first segment to the second segment, wherein the first segment and the second segment are disposed opposite to each other in a direction perpendicular to a plane where the first segment is located, the first segment comprises a display region, and the second segment comprises a binding region;
a first support layer located on a side of the first segment close to the second segment;
a second support layer located on a side of the second segment close to the first segment;
a function layer located between the first support layer and the second support layer;
a binding element comprising a first overlapping portion, a second overlapping portion, and a connection portion connecting the first overlapping portion to the second overlapping portion, wherein the first overlapping portion is in binding connection with the binding region, the second overlapping portion is connected to the function layer through a first bonding layer, and an accommodation space is formed between the connection portion and the function layer; and
a second bonding layer comprising a first sub-bonding portion and a second sub-bonding portion that are in mutual contact, wherein the first sub-bonding portion is located between the second support layer and the function layer;
wherein a sidewall of the second support layer close to the accommodation space is a first sidewall, the second sub-bonding portion is located in the accommodation space, and the second sub-bonding portion covers at least one of: at least part of the first sidewall or an edge of an overlapping region of the first overlapping portion and the second segment.

2. The display module of claim 1, wherein the second sub-bonding portion is filled within the accommodation space and is in contact with the connection portion, the first bonding layer and the function layer separately.

3. The display module of claim 2, wherein a distance between the connection portion and the function layer gradually decreases in a direction in which the first overlapping portion is directed towards the second overlapping portion, and a thickness of the second sub-bonding portion gradually decreases in the direction in which the first overlapping portion is directed towards the second overlapping portion.

4. The display module of claim 3, wherein a thickness of the first sub-bonding portion is less than or equal to a thickness of the first bonding layer.

5. The display module of claim 3, wherein a maximum thickness of the second sub-bonding portion is equal to a sum of thicknesses of the second segment, the second support layer, and the first sub-bonding portion.

6. The display module of claim 3, wherein a minimum thickness of the second sub-bonding portion is equal to a thickness of the first bonding layer.

7. The display module of claim 2, wherein the first bonding layer comprises a main portion and an extension portion, and the extension portion is located on a side of the main portion close to the second bonding layer; the extension portion comprises an arc surface, and the arc surface of the extension portion is bent towards the function layer; a sidewall of the main portion close to the second bonding layer is a second sidewall, the arc surface of the extension portion is connected to the second sidewall, and the second sub-bonding portion is in contact with the arc surface of the extension portion and the second sidewall separately.

8. The display module of claim 1, wherein a surface of the second sub-bonding portion close to the first bonding layer is an arc surface.

9. The display module of claim 1, wherein,
the first sidewall comprises at least one first groove, a surface of the second sub-bonding portion away from the first bonding layer comprises at least one first protrusion, and a first protrusion of the at least one first protrusion is fitted into a respective one of the at least one first groove; or
the first sidewall comprises at least one second protrusion, a surface of the second sub-bonding portion away from the first bonding layer comprises at least one second groove, and a second protrusion of the at least one second protrusion is fitted into a respective one of the at least one second groove.

10. The display module of claim 9, wherein the at least first groove is located in a portion of the first sidewall close to the function layer; or
the at least one second protrusion is located in a portion of the first sidewall close to the function layer.

11. The display module of claim 1, wherein a hardness of the first sub-bonding portion is greater than a hardness of the second sub-bonding portion.

12. The display module of claim 1, wherein the first sub-bonding portion and the second sub-bonding portion form an integrative structure.

13. The display module of claim 2, wherein a distance between the first overlapping portion and the function layer is equal to a distance between the second overlapping portion and the function layer, and a thickness of the second sub-bonding portion is equal at different positions of the second sub-bonding portion.

14. The display module of claim 1, wherein a material of the first bonding layer is different from a material of the second bonding layer.

15. The display module of claim 1, wherein the function layer comprises a composite film layer, and the composite film layer comprises an adhesive layer, a metal layer, and foam which are disposed in a stacked manner.

16. The display module of claim 1, further comprising:
an optical film layer located on a side of the first segment away from the function layer; and
a cover plate located on a side of the optical film layer away from the first segment.

17. A preparation method of a display module, comprising:
providing a display panel, wherein the display panel comprises a first segment, a second segment, and a bending portion connecting the first segment to the second segment, the first segment comprises a display region, and the second segment comprises a binding region;
forming a first support layer on a side of the first segment, and forming a second support layer on a side of the second segment;
providing a binding element, wherein the binding element comprises a first overlapping portion, a second overlapping portion, and a connection portion connecting the first overlapping portion to the second overlapping portion, and the first overlapping portion is in binding connection with the binding region;
forming a function layer on a side of the first support layer away from the first segment;
providing a bonding structure, wherein the bonding structure comprises a first protective film, a second protective film, and a first bonding layer and a second bonding layer that are located between the first protective film and the second protective film, and the second bonding layer comprises a first sub-bonding portion and a second sub-bonding portion which are contacted with each other;
removing the first protective film to attach the first bonding layer and the second bonding layer to a side of the function layer away from the first segment, and removing the second protective film; and
bending the display panel so that the second overlapping portion is connected to the function layer through the first bonding layer, and the second support layer is connected to the function layer through the first sub-bonding portion; wherein an accommodation space is formed between the connection portion and the function layer, a sidewall of the second support layer close to the accommodation space is a first sidewall, the second sub-bonding portion is located in the accommodation space, and the second sub-bonding portion covers at least one of: at least part of the first sidewall or an edge of an overlapping region of the first overlapping portion and the second segment.

18. The preparation method of claim 17, wherein the first sub-bonding portion and the second sub-bonding portion form an integrative structure in the bonding structure.

19. The preparation method of claim 17, wherein the second sub-bonding portion is filled within the accommodation space and is in contact with the connection portion, the first bonding layer, and the function layer separately.

20. A display device, comprising a display module;
wherein the display module comprising:
a display panel comprising a first segment, a second segment, and a bending portion connecting the first segment to the second segment, wherein the first segment and the second segment are disposed opposite to each other in a direction perpendicular to a plane where the first segment is located, the first segment comprises a display region, and the second segment comprises a binding region;
a first support layer located on a side of the first segment close to the second segment;
a second support layer located on a side of the second segment close to the first segment;
a function layer located between the first support layer and the second support layer;
a binding element comprising a first overlapping portion, a second overlapping portion, and a connection portion connecting the first overlapping portion to the second overlapping portion, wherein the first overlapping portion is in binding connection with the binding region, the second overlapping portion is connected to the function layer through a first bonding layer, and an accommodation space is formed between the connection portion and the function layer;
a second bonding layer comprising a first sub-bonding portion and a second sub-bonding portion that are in mutual contact, wherein the first sub-bonding portion is located between the second support layer and the function layer;
wherein a sidewall of the second support layer close to the accommodation space is a first sidewall, the second sub-bonding portion is located in the accommodation space, and the second sub-bonding portion covers at least one of: at least part of the first sidewall or an edge of an overlapping region of the first overlapping portion and the second segment.
